(19) United States
(12) Patent Application Publication
(10) Pub. No.: US 2005/0214695 A1
(43) Pub. Date: Sep. 29, 2005

(54) Pattern forming method and method for manufacturing semiconductor device

(76) Inventors: Hirokazu Kato, Zushi-shi (JP); Yasunobu Onishi, Yokohama-shi (JP); Daisuke Kawamura, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/081,579

(22) Filed: Mar. 17, 2005

(30) Foreign Application Priority Data
Mar. 24, 2004 (JP) 2004-087419

(51) Int. Cl. G03F 7/00

(52) U.S. Cl. 430/324; 430/323

(57) ABSTRACT

A pattern forming method which can suppress pattern collapse of a resist pattern comprises after developing a resist pattern formed from a resist film on a substrate, supplying a rinse agent onto the substrate to replace a developer on the substrate with the rinse agent, supplying an coating film material onto the substrate to replace at least a part of the rinse agent with the coating film material, wherein the coating film material contains a solvent and a solute different from the resist film, volatilizing the solvent in the coating film material to form an coating film covering the resist film on the substrate, removing at least a part of a surface of the coating film to expose at least a part of an upper surface of the resist pattern and form a mask pattern comprising the coating film, and processing the substrate using the mask pattern.

### CROSS-REFERENCE TO RELATED APPLICATIONS

This application is based upon and claims the benefit of priority from prior Japanese Patent Application No. 2004-087419, filed Mar. 24, 2004, the entire contents of which are incorporated herein by reference.

### BACKGROUND OF THE INVENTION

1. Field of the Invention

The present invention relates to a pattern forming method which suppresses occurrence of a defect due to pattern collapse of a resist and a method for manufacturing a semiconductor device using the pattern forming method.

2. Description of the Related Art

In recent years, realization of a fine structure of a pattern has advanced, and a pattern collapse of a resist which occurs in a lithography process has become a serious problem. As main factors of the pattern collapse, there can be considered a surface tension and a flow drag of a rinse agent when drying the rinse agent. Above all things, an influence of the surface tension becomes larger in a fine patterning. According to H. Namatsu et al., Appl. Phys. Lett. 66, 2655 (1955), when drying a rinse agent, a vertical stress σ applied to a resist pattern can be represented as follows:
σ=6γcosθ/D×(H/W)² (1)
where W is a line width, D is a space width, H is a pattern height, γ is a surface tension of the rinse agent, and θ is an angle formed at an interface between a rinse agent and a resist side wall. As a resolution to the problem, the most effective method is a reduction in film thickness of a resist, but the method is reaching its limit in view of a substrate processing. In recent years, although a three-layered resist process or a hard mask process has been used in order to further reduce the film thickness from the limit, however, the limit still exists in a reduction in the resist film thickness, thus an essential resolution is not achieved.

Further, applications of processes using techniques disclosed in specifications of Japanese Patent No. 2723260, Japanese Patent No. 3057879, Japanese Patent No. 3071401, Japanese Patent No. 3218814, Japanese Patent No. 3476080, Japanese Patent No. 3476081, and Japanese Patent No. 3476082 (which will be collectively referred to as a shrink process hereinafter) has been spreading. The process is mainly used for a layer having a hole pattern which is hard to secure a lithography margin. A flow of the shrink process is generally as follows. After a resist pattern is formed, a solution containing a pattern shrink material is coated. Subsequently, a reaction layer is formed on a resist pattern surface. The reaction layer is, e.g., a mixed layer, a bridging layer, a coating layer or the like, and it differs depending on type of the pattern shrink materials. At last, an unreacted layer is removed, thereby obtaining a hole or space pattern smaller than the original pattern. However, when a hole pattern and a line-and-space pattern are coexisted, a problem can be occurred. When a ratio of a line width to a space width is desired to be processed close to 1:1 as much as possible after applying the shrink process, the pattern after the lithography must be finished so that the line width is finer than the space width. Modifying Eq. (1) by setting a patch in the line-and-space pattern as P, the following expression can be obtained:
σ=6γcosθ/(P−W)×(H/W)² (2)
Here, a dependence of the vertical stress a on the line width W can be represented as follows.
∂σ∂W=−6γcosθ×(2PW²−3W²)/(PW²−W³)² (3)
Therefore, when W=2P/3, i.e., a ratio of the line width to the space width is 2:1, it can be understood that the vertical stress can take a minimal value. That is, in case of the same pitch, pattern collapse is apt to occur in drying the rinse agent as the line is finished to be finer beyond the ratio 2:1. This problem becomes more prominent as the pattern pitch becomes finer and as a degree of shrink in the shrink process becomes larger.

Therefore, there is a need for a pattern forming method which can suppress pattern collapse of a resist pattern and a method for manufacturing a semiconductor device using this pattern forming method.

### BRIEF SUMMARY OF THE INVENTION

According to an aspect of the present invention, a pattern forming method comprises: forming a resist film on a substrate; selectively irradiating an energy beam on the resist film in order to form a latent image in the resist film; supplying a developer onto the resist film in order to form a resist pattern from the resist film having the latent image formed therein; supplying a rinse agent onto the substrate in order to replace the developer on the substrate with the rinse agent; supplying an coating film material onto the substrate in order to replace at least a part of the rinse agent on the substrate with the coating film material, wherein the coating film material contains a solvent and a solute different from the resist film; volatilizing the solvent in the coating film material in order to form an coating film covering the resist film on the substrate; removing at least a part of a surface of the coating film in order to expose at least a part of an upper surface of the resist pattern and form a mask pattern comprising the coating film; and processing the substrate using the mask pattern.

According to another aspect of the present invention, a pattern forming method comprises: forming a resist film on a substrate; selectively irradiating an energy beam on the resist film in order to form a latent image in the resist film; supplying a developer onto the resist film in order to form a resist pattern from the resist film having the latent image formed therein; supplying an coating film material onto the resist film in order to replace at least a part of the developer on the resist film with the coating film material, wherein the coating film material contains a solvent and a solute different from the resist film; forming a film which volatilizes the solvent in the coating film material in order to form an coating film covering the resist pattern on the substrate; removing at least a part of a surface of the coating film in order to expose at least a part of an upper surface of the resist pattern and form a mask pattern comprising the coating film; and processing the substrate using the mask pattern.

According to still another aspect of the present invention, a pattern forming method comprises: forming a resist film on a substrate; selectively irradiating an energy beam on the resist film in order to form a latent image in the resist film; supplying a developer onto the resist film in order to form a resist pattern from the resist film having the latent image formed therein; supplying a rinse agent onto the substrate in order to replace the developer on the substrate with the rinse agent; supplying an coating film material onto the substrate in order to replace at least a part of the rinse agent on the substrate with the coating film material, wherein the coating film material contains a solvent and a solute different from the resist film; forming a film which volatilizes the solvent in the coating film forming material in order to form an coating film covering the resist film on the substrate; forming a reaction layer at an interface between the resist film and the coating film; and selectively removing the coating film in order to form a mask pattern in which the resist pattern and the reaction layer are laminated on the substrate.

According to yet another aspect of the present invention, a pattern forming method comprises: forming a resist film on a substrate; selectively irradiating an energy beam on the resist film in order to form a latent image in the resist film; supplying a developer onto the resist film in order to form a resist pattern from the resist film having the latent image formed therein; supplying an coating film material onto the substrate in order to replace at least a part of the developer on the substrate with the coating film material, wherein the coating film material contains a solvent and a solute different from the resist film; forming a film which volatilizes the solvent in the coating film material in order to form an coating film covering the resist film on the substrate; forming a reaction layer at an interface between the resist film and the coating film; and selectively removing the coating film in order to form a mask pattern in which the resist pattern and the reaction layer are laminated on the substrate.

According to further aspect of the present invention, a method for manufacturing a semiconductor device comprises: forming a mask pattern on a semiconductor substrate which is in a process of manufacturing a semiconductor device; and processing the semiconductor substrate with the mask pattern being used as a mask; the forming the mask pattern comprises, forming a resist film on the semiconductor substrate, selectively irradiating an energy beam on the resist film in order to form a latent image in the resist film, supplying a developer onto the resist film in order to form a resist pattern from the resist film having the latent image formed therein, supplying a liquid agent which stops a development onto the semiconductor substrate in order to replace at least a part of the developer on the semiconductor substrate with the liquid agent, supplying an coating film material onto the semiconductor substrate and volatilizing the solvent in the coating film material in order to form an coating film covering the resist film on the semiconductor substrate, and removing at least a part of a surface of the coating film in order to expose at least a part of an upper surface of the resist pattern and form a mask pattern comprising the coating film.

According to further aspect of the present invention, a method for manufacturing a semiconductor device comprises: forming a mask pattern on a semiconductor substrate which is in a process of manufacturing a semiconductor device; and processing the semiconductor substrate with the mask pattern being used as a mask; the forming the mask pattern comprises, forming a resist film on the semiconductor substrate, selectively irradiating an energy beam on the resist film in order to form a latent image in the resist film, supplying a developer onto the resist film in order to form a resist pattern from the resist film having the latent image formed therein, supplying a liquid agent which stops a development onto the semiconductor substrate in order to replace at least a part of the developer on the semiconductor substrate with the liquid agent, supplying an coating film material onto the semiconductor substrate and volatilizing the solvent in the coating film material in order to form an coating film covering the resist film on the semiconductor substrate, forming a reaction layer at an interface between the resist film and the coating film, and selectively removing the coating film in order to form a mask pattern in which the resist pattern and the reaction layer are laminated on the semiconductor substrate.

### BRIEF DESCRIPTION OF THE SEVERAL VIEWS OF THE DRAWING

FIGS. 1A to 1K are cross-sectional views illustrating an example of a semiconductor manufacturing process according to a first embodiment of the present invention; and

FIGS. 2A to 2J are cross-sectional views illustrating an example of a semiconductor manufacturing process according to a second embodiment of the present invention.

### DETAILED DESCRIPTION OF THE INVENTION

The embodiments of the present invention will be described with reference to the accompanying drawings. Throughout the drawings, corresponding portions are denoted by correspondent reference numerals.

(First Embodiment)

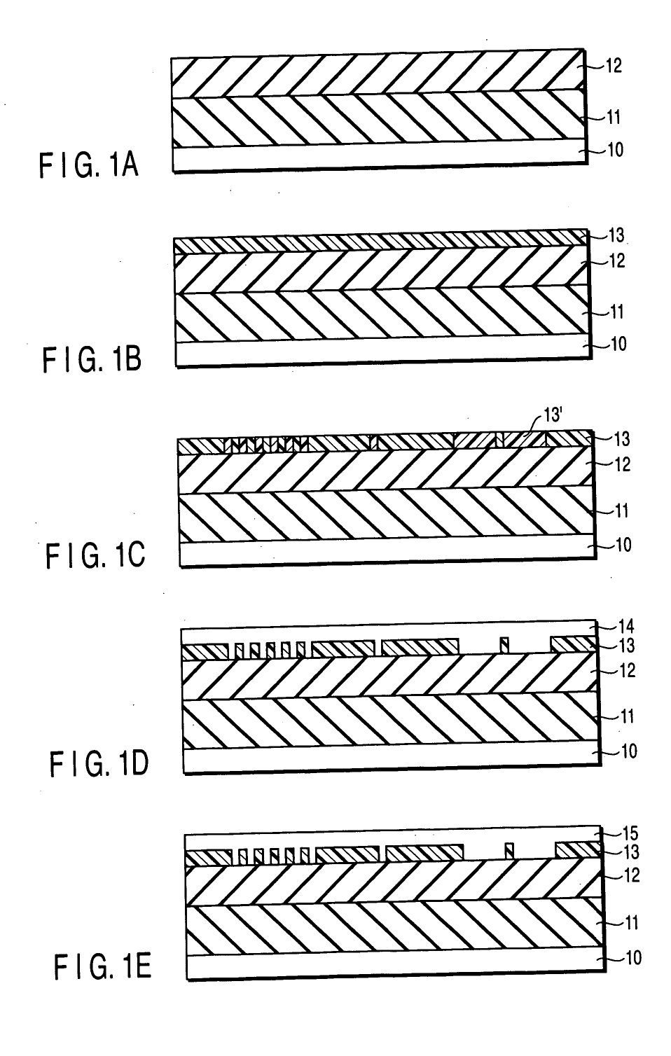

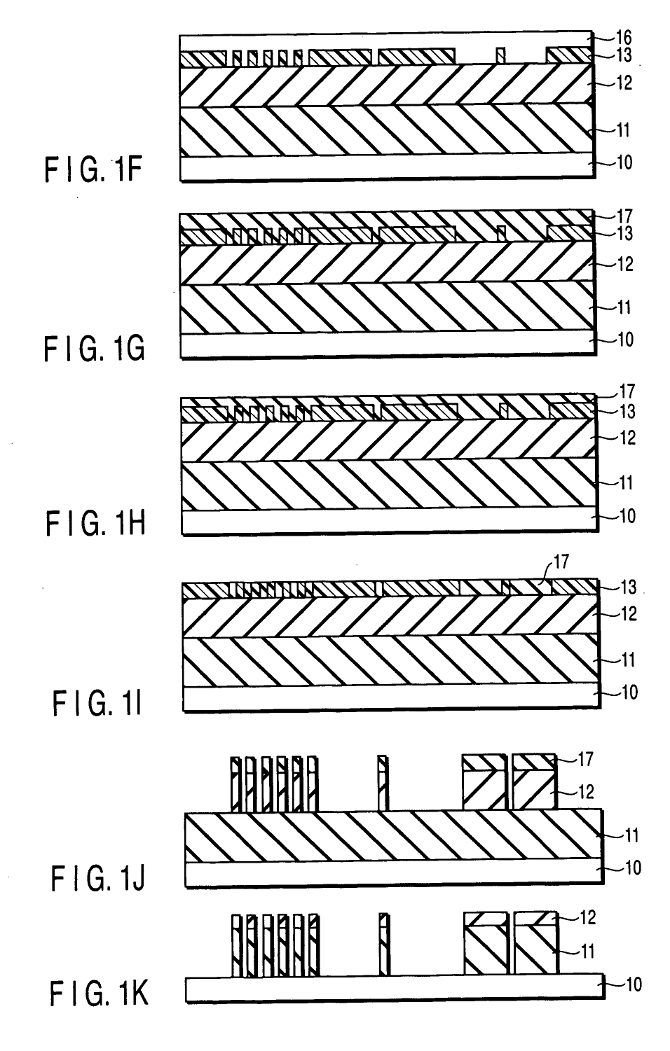

FIGS. 1A to 1K are cross-sectional views illustrating an example of a semiconductor manufacturing process according to a first embodiment of the present invention.

As shown in FIG. 1A, a novolak film (a lower mask layer) 12 having a film thickness of, e.g., a 500 nm is formed on an interlevel insulator 11 formed on a semiconductor substrate 10. As shown in FIG. 1B, e.g., an ArF resist film 13 having a film thickness of 150 nm is formed on the novolak film 12.

As shown in FIG. 1C, a pattern formed on a mask is transferred to the resist film 13 by using, e.g., an ArF excimer laser exposure device. The resist film 13 is baked for, e.g., 60 seconds at 130° C. As a result, a latent image 13′ is formed in the resist film 13. It is to be noted that the latent image formed in the resist film 13 has a reversal pattern of a desired pattern.

As shown in FIG. 1D, a developer 14 is applied and spread on the ArF resist film 13, and development is performed for, e.g., 60 seconds in order to form a resist pattern. As to a target dimension of the resist pattern 13 to be formed, each of a line width and a space width is 70 nm in a line-and-space pattern portion, for example.

As shown in FIG. 1E, a rinse agent 15 is supplied to the surface of the resist pattern 13, the developer 14 is replaced with the rinse agent 15.

As shown in FIG. 1F, a water-soluble silicone solution 16 is discharged onto the resist pattern 13, and at least a part of the rinse agent 15 is replaced with the water-soluble silicone solution 16.

As shown in FIG. 1G, the substrate is spun to volatilize a solvent in the water-soluble silicone solution, and a water-soluble silicone film 17 is formed to cover the resist pattern 13. As shown in FIG. 1H, baking is carried out for, e.g., 60 seconds at 100° C., and the water-soluble silicone film 17 is cured.

As shown in FIG. 1I, the water-soluble silicone film 17 is etched back by using fluorocarbon gas plasma so that an upper surface of the resist pattern is exposed. The water-soluble silicone film pattern (a mask pattern) 17 is formed by the etching. The water-soluble silicone film pattern 17 is the above-described desired pattern.

As shown in FIG. 1J, anisotropic etching is performed by using oxygen plasma to selectively etch the resist pattern 13 and the novolak film 12. As shown in FIG. 1K, the interlevel insulator 11 is etched with the water-soluble silicone film pattern 17 and the novolak film 12 being used as a mask.

A pattern collapse is apt to occur in drying processing. Since the processing of drying the rinse agent 15 is not performed in the embodiment, the pattern collapse can be suppressed. In the embodiment, without performing the drying processing of the rinse agent 15, a processing is performed by replacing the rinse agent 15 with the water-soluble silicone solution 16, forming the water-soluble silicone film 17, forming a pattern on the water-soluble silicone film 17, and selectively removing the resist pattern 13.

In the present embodiment, the description has been given as to the example where the ArF resist film is used as the resist film and the ArF exposure device is used as the exposure device, the embodiment of the present invention is not limited thereto. It can be used a resist film having sensitivity with respect to g-line, i-line, KrF, F₂, EUV, an electron beam or others, and an exposure device corresponding to each member.

Furthermore, the rinse agent is replaced with the water-soluble silicone in the embodiment, but replacement may be completely or partially carried out. Moreover, the substrate may be stationary or be spun during the replacement processing.

Additionally, although etching back is performed in the embodiment, it can be used various known techniques, e.g., a use of CMP as disclosed in Jpn. Pat. Appln. KOKAI Publication No. 2000-310863, or a use of wet etching as disclosed in Jpn. Pat. Appln. KOKAI Publication No. 2002-110510. Further, the present invention can be embodied by combining with a technique disclosed in U.S. patent application Ser. No. 10/839,184 filed on May 6, 2004.

It is to be noted that, after supplying the developer 14, the water-soluble silicone solution 16 can be supplied to replace at least a part of the developer 14 with the water-soluble silicone solution 16 without supplying the rinse agent 15.

(Second Embodiment)

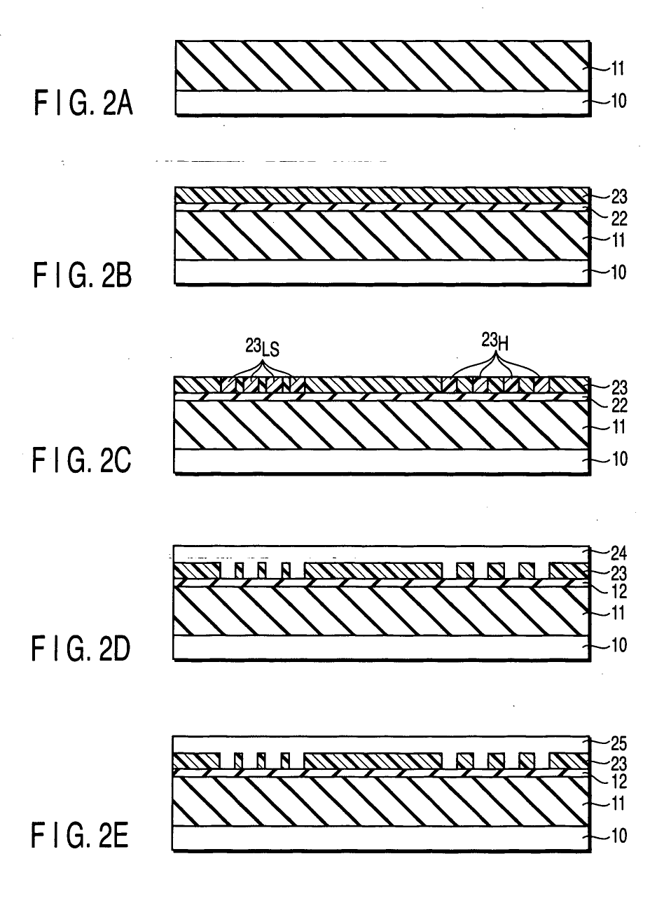

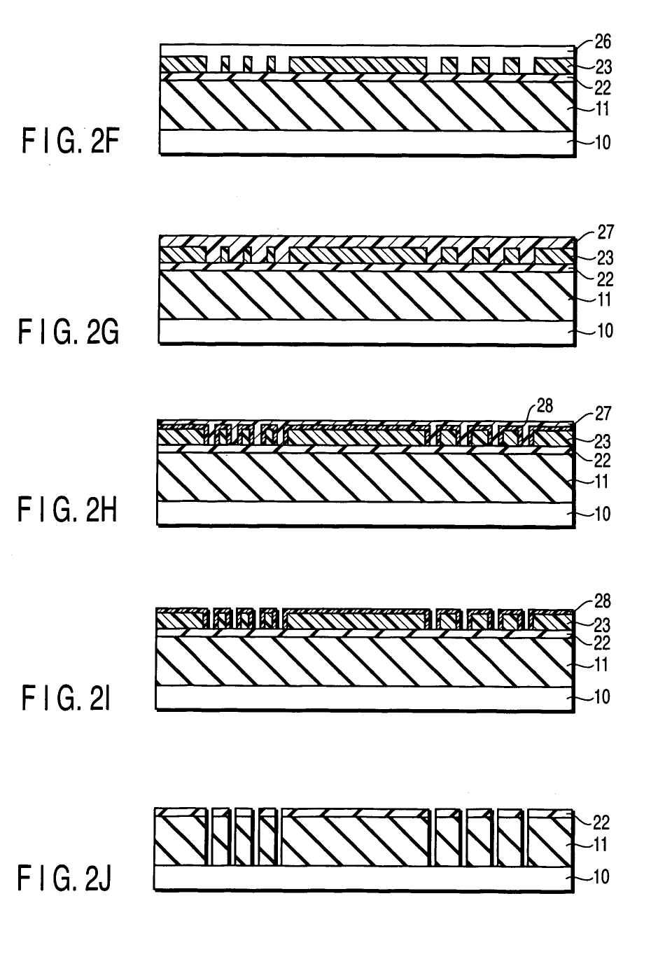

A second embodiment according to the present invention will now be described hereinafter with reference to FIGS. 2A to 2J. FIGS. 2A to 2J are cross-sectional views illustrating an example of a semiconductor device manufacturing process according to the second embodiment of the present invention.

As shown in FIG. 2A, an anti-reflection film 22 having a film thickness of 82 nm is formed on an interlevel insulator 11 formed on a semiconductor substrate 10. As shown in FIG. 2B, an ArF resist film 23 having a film thickness of 150 nm is formed on the anti-reflection film 22.

As shown in FIG. 2C, a pattern formed on a mask is transferred to the resist film 23 by using, e.g., an ArF excimer laser exposure device. The resist film 23 is baked for, e.g., 60 seconds at 130° C. As a result, a latent image 23_{H} and a latent image 23_{LS} are formed in the resist film 23. It is to be noted that the latent image 23_{H} is a latent image which is used to form a hole pattern. Furthermore, the latent image 23_{LS} is a latent image which is used to form a line-and-space pattern. As to a target dimension of the resist pattern, the hole pattern has a dimension of 150 nm, and the line-and-space pattern has a line width of 40 nm and a space width of 100 nm.

As shown in FIG. 2D, a developer 24 is applied and spread on the ArF resist film 23, and development is carried out for, e.g., 60 seconds. As shown in FIG. 2E, the rinse agent 25 is discharged onto the resist film 23, and the developer is replaced with the rinse agent 25. As shown in FIG. 2F, a solution 26 which is used to form a coating film for pattern shrink is discharged, and the rinse agent 25 is replaced with the solution 26. As shown in FIG. 2G, the substrate 10 is spun to volatilize a solvent in the solution 26, and a coating film 27 is formed to cover the resist pattern 23. As shown in FIG. 2H, baking is carried out for, e.g., 60 seconds at 130° C. in order the coating film 27 to react with the resist film 23, thereby forming a reaction layer 28 at an interface between the coating film 27 and the resist film 23.

As shown in FIG. 2I, the solvent contained in the solution 26 is supplied onto the coating film 27, and an unreacted coating film 27 is selectively removed. As to the pattern dimension, the hole pattern has a dimension of 120 nm, and the line-and-space pattern has a line width of 70 nm and a space width of 70 nm. Incidentally, when the resist pattern 23 having the reaction layer 28 formed on the surface thereof was observed under an electron microscope, no patter collapse was observed in the line-and-space pattern.

As shown in FIG. 2J, the anti-reflection film 22 and the interlevel insulator 11 are etched with the reaction layer 28 and the resist film 23 being used as a mask.

The pattern collapse is apt to occur in the processing of drying the rinse agent. Since the processing of drying the rinse agent 25 is not performed in the embodiment, the pattern collapse can be suppressed. In the embodiment, without performing the drying processing of the rinse agent 25, the processing is performed by replacing the rinse agent 25 with the solution 26 to form the coating film for pattern shrink, forming the coating film 27, forming the reaction layer 28, and selectively removing the unreacted coating film 27.

The pattern collapse is apt to occur in the drying processing of the rinse agent when the line is finished to be finer beyond the ratio 2:1 of the line width to the space width. Therefore, it is preferable to apply the pattern forming method according to the embodiment when the line is finer beyond the ratio 2:1 of the line width to the space width.

Although the rinse agent 25 is replaced with the solution 26 in the embodiment, replacement may be completely or partially performed. Moreover, the substrate may be stationary or be spun during the replacement processing.

It is to be noted that, after supplying the developer 24, the solution 26 can be supplied to replace at least a part of the developer 24 with the solution 26 without supplying the rinse agent 25.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

1. A pattern forming method comprising:
forming a resist film on a substrate;
selectively irradiating an energy beam on the resist film in order to form a latent image in the resist film;
supplying a developer onto the resist film in order to form a resist pattern from the resist film having the latent image formed therein;
supplying a rinse agent onto the substrate in order to replace the developer on the substrate with the rinse agent;
supplying an coating film material onto the substrate in order to replace at least a part of the rinse agent on the substrate with the coating film material, wherein the coating film material contains a solvent and a solute different from the resist film;
volatilizing the solvent in the coating film material in order to form an coating film covering the resist film on the substrate;
removing at least a part of a surface of the coating film in order to expose at least a part of an upper surface of the resist pattern and form a mask pattern comprising the coating film; and
processing the substrate using the mask pattern.

2. The pattern forming method according to claim 1, wherein an etching rate of the coating film with oxygen plasma is lower than an etching rate of the resist film with oxygen plasma.

3. The pattern forming method according to claim 1, wherein the coating film material is water-soluble silicone.

4. A pattern forming method comprising:
forming a resist film on a substrate;
selectively irradiating an energy beam on the resist film in order to form a latent image in the resist film;
supplying a developer onto the resist film in order to form a resist pattern from the resist film having the latent image formed therein;
supplying an coating film material onto the resist film in order to replace at least a part of the developer on the resist film with the coating film material, wherein the coating film material contains a solvent and a solute different from the resist film;
forming a film which volatilizes the solvent in the coating film material in order to form an coating film covering the resist pattern on the substrate;
removing at least a part of a surface of the coating film in order to expose at least a part of an upper surface of the resist pattern and form a mask pattern comprising the coating film; and
processing the substrate using the mask pattern.

5. The pattern forming method according to claim 4, wherein an etching rate of the coating film with oxygen plasma is lower than an etching rate of the resist film with oxygen plasma.

6. The pattern forming method according to claim 4, wherein the coating film material is water-soluble silicone.

7. A pattern forming method comprising:
forming a resist film on a substrate;
selectively irradiating an energy beam on the resist film in order to form a latent image in the resist film;
supplying a developer onto the resist film in order to form a resist pattern from the resist film having the latent image formed therein;
supplying a rinse agent onto the substrate in order to replace the developer on the substrate with the rinse agent;
supplying an coating film material onto the substrate in order to replace at least a part of the rinse agent on the substrate with the coating film material, wherein the coating film material contains a solvent and a solute different from the resist film;
forming a film which volatilizes the solvent in the coating film forming material in order to form an coating film covering the resist film on the substrate;
forming a reaction layer at an interface between the resist film and the coating film; and
selectively removing the coating film in order to form a mask pattern in which the resist pattern and the reaction layer are laminated on the substrate.

8. The pattern forming method according to claim 7, wherein the mask pattern comprises a line and space pattern in which a ratio of a line width to a space width is smaller than 2:1.

9. The pattern forming method according to claim 7, further comprising:
forming an anti-reflection film on the substrate.

10. A pattern forming method comprising:
forming a resist film on a substrate;
selectively irradiating an energy beam on the resist film in order to form a latent image in the resist film;
supplying a developer onto the resist film in order to form a resist pattern from the resist film having the latent image formed therein;
supplying a coating film material onto the substrate in order to replace at least a part of the developer on the substrate with the coating film material, wherein the coating film material contains a solvent and a solute different from the resist film;
forming a film which volatilizes the solvent in the coating film material in order to form an coating film covering the resist film on the substrate;
forming a reaction layer at an interface between the resist film and the coating film; and
selectively removing the coating film in order to form a mask pattern in which the resist pattern and the reaction layer are laminated on the substrate.

11. The pattern forming method according to claim 10, wherein the mask pattern comprises a line and space pattern in which a ratio of a line width to a space width is smaller than 2:1.

12. The pattern forming method according to claim 10, further comprising:
forming an anti-reflection film on the substrate.

13. A method for manufacturing a semiconductor device, comprising: forming a mask pattern on a semiconductor substrate which is in a process of manufacturing a semiconductor device; and processing the semiconductor substrate with the mask pattern being used as a mask; the forming the mask pattern comprising,
forming a resist film on the semiconductor substrate,
selectively irradiating an energy beam on the resist film in order to form a latent image in the resist film,
supplying a developer onto the resist film in order to form a resist pattern from the resist film having the latent image formed therein,
supplying a liquid agent which stops a development onto the semiconductor substrate in order to replace at least a part of the developer on the semiconductor substrate with the liquid agent,
supplying an coating film material onto the semiconductor substrate and volatilizing a solvent in the coating film material in order to form an coating film covering the resist film on the semiconductor substrate, and
removing at least a part of a surface of the coating film in order to expose at least a part of an upper surface of the resist pattern and form a mask pattern comprising the coating film.

14. The method according to claim 13, wherein the liquid agent is a rinse agent.

15. The method according to claim 13, wherein the liquid agent is a coating film material.

16. A method for manufacturing a semiconductor device, comprising: forming a mask pattern on a semiconductor substrate which is in a process of manufacturing a semiconductor device; and processing the semiconductor substrate with the mask pattern being used as a mask; the forming the mask pattern comprising,
forming a resist film on the semiconductor substrate,
selectively irradiating an energy beam on the resist film in order to form a latent image in the resist film,
supplying a developer onto the resist film in order to form a resist pattern from the resist film having the latent image formed therein,
supplying a liquid agent which stops a development onto the semiconductor substrate in order to replace at least a part of the developer on the semiconductor substrate with the liquid agent,
supplying an coating film material onto the semiconductor substrate and volatilizing a solvent in the coating film material in order to form an coating film covering the resist film on the semiconductor substrate,
forming a reaction layer at an interface between the resist film and the coating film, and
selectively removing the coating film in order to form a mask pattern in which the resist pattern and the reaction layer are laminated on the semiconductor substrate.

17. The method according to claim 16, wherein the liquid agent is a rinse agent.

18. The method according to claim 16, wherein the liquid agent is a coating film material.

19. The method according to claim 16, the forming the mask pattern further comprising,
forming an anti-reflection film on the semiconductor substrate.
